(19) United States
(12) Patent Application Publication
(10) Pub. No.: US 2010/0054055 A1
(43) Pub. Date: Mar. 4, 2010

(54) DATA INPUT/OUTPUT CIRCUIT

(75) Inventors: Hoon CHOI, Gyeonggi-do (KR); Jin-II Chung, Gyeonggi-do (KR)

Correspondence Address: IP & T Law Firm PLC, 7700 Little River Turnpike, Suite 207, Annandale, VA, 22003, US

(73) Assignee: HYNIX SEMICONDUCTOR, INC., Gyeonggi-do (KR)

(21) Appl. No.: 12/345,654

(22) Filed: Dec. 29, 2008

(30) Foreign Application Priority Data
Sep. 2, 2008 (KR) 10-2008-0086110

(51) Int. Cl. G11C 7/00; G11C 8/18

(52) U.S. Cl. 365/193; 365/194; 365/198; 365/233.1

(57) ABSTRACT

A data input/output circuit includes an output unit for outputting a first data strobe signal and first data in response to an internal clock generated in a delay locked loop, a first transmission line unit having a clock tree structure for transmitting the internal clock to the output unit, a second transmission line unit for transmitting the internal clock from the delay locked loop to the first transmission line unit, a duty cycle ratio correcting unit interconnected between the first transmission line unit and the second transmission line unit for correcting a duty cycle ratio of the internal clock, a data strobe signal input unit for receiving a second data strobe signal from an outside of a semiconductor memory device and generating an internal data strobe signal, and a plurality of data input units for outputting a second data in response to the internal data strobe signal.

### CROSS-REFERENCE TO RELATED APPLICATION

The present invention claims priority of Korean patent application number 10-2008-0086110, filed on Sep. 2, 2008, which is incorporated by reference in its entirety.

### BACKGROUND OF THE INVENTION

The present invention relates to a data input/output circuit of a semiconductor memory device, and more particularly, to a data input/output circuit having improved jitter characteristics.

A synchronous semiconductor memory device is synchronized with a clock provided from an external device. Particularly, a double data rate (DDR) synchronous semiconductor memory device is synchronized with a rising edge and a falling edge of a clock inputted from an external device, thereby processing two-bit data in one clock cycle. The DDR synchronous semiconductor memory device includes a delay locked loop (DLL) circuit for accurate timing of data input/output.

It is very important to precisely control a duty cycle ratio of a clock in a synchronous semiconductor memory device. If it fails to accurately control the duty cycle ratio, data may be distorted due to lack of data margin.

The duty cycle ratio is a ratio of a duration of a high level period and a duration of a low level period in one clock cycle. For example, a duty cycle ratio of 50:50 means that the high level period and the low level period occupy the same amount of time in one clock cycle.

FIG. 1 is a diagram illustrating a data input/output circuit according to the related art.

As shown in FIG. 1, the conventional data input/output circuit includes a data output circuit 101, a data input circuit 103, and a plurality of DQ pads 105.

The data output circuit 101 and the data input circuit 103 output or receive data bi-directionally through one DQ pad. That is, in the case of a read operation of a semiconductor memory device, while the data input circuit 103 is not receiving data from an external device through the DQ pad, the data output circuit 101 outputs data to an external device through the DQ pad. In the case of a write operation of the semiconductor memory device, the data input circuit 103 receives data through the DQ pad, while the data output circuit 101 is not outputting data through the DQ pad.

FIG. 2 is a diagram illustrating a data output circuit 101 of FIG. 1.

As shown in FIG. 2, the data output circuit 101 includes a first transmission line unit 203, a second transmission line unit 201, an output unit 205, and an output controller 217.

The second transmission line unit 201 transfers internal clocks RCLK_DLL and FCLK_DLL, which are generated by a delay locked loop (shown in FIG. 3) based on an external clock EXT_CLK to correct a clock skew of a semiconductor memory device, to the first transmission line unit 203. The second transmission line unit 201 may optionally include a repeater 219 for preventing the distortion of the internal clocks RCLK_DLL and FCLK_DLL.

The first transmission line unit 203 transmits internal clocks RCLK_DLL and FCLK_DLL to the output unit 205. The output unit 205 includes a data strobe signal output unit 207 for outputting a data strobe signal DQS by using the internal clocks RCLK_DLL and FCLK_DLL and a plurality of data output units 209, 211, 213, and 215 for outputting internal data DATA as external data DQ in response to the internal clocks RCLK_DLL and FCLK_DLL. The first transmission line unit 203 has a clock tree structure for minimizing skew between the internal clocks RCLK_DLL and FCLK_DLL, which are transmitted to the data output units 209, 211, 213, and 215 and the data strobe signal output unit 207.

Each of the data output units 209, 211, 213, and 215, connected to corresponding DQ pad, latches the internal data outputted from a memory cell of the semiconductor memory device at rising edges of the internal clock RCLK_DLL and FCLK_DLL and outputs the latched internal data to a memory controller. The data strobe signal output unit 207 outputs the data strobe signal DQS to the memory controller. Since the data output units 209, 211, 213, 215, and the data strobe signal output unit 207 output the external data DQ and the data strobe signal DQS based on the internal clocks RCLK_DLL and FCLK_DLL, the phase of the external data DQ is matched with that of the data strobe signal DQS.

The memory controller receives the external data DQ outputted from the data output units 209, 211, 213, and 215 based on the data strobe signal DQS outputted from the data strobe signal output unit 207.

The output controller 217 controls the output unit 205 in response to a mode signal MODE according to an operation mode of the semiconductor memory device. For example, the output controller 217 enables first and second output control signals DQ_EN and DQS_EN only for a write operation of a semiconductor memory device, and the data output units 209, 211, 213, and 215 and the repeater 219 are enabled in response to the first and second output control signals DQ_EN and DQS_EN in order to reduce power consumption of the semiconductor memory device.

FIG. 3 is a diagram illustrating a delay locked loop circuit mentioned in the description of FIG. 2.

The delay locked loop circuit includes a phase comparator 301, a delay controller 303, a replica model unit 305, and a duty cycle ratio corrector 307.

The phase comparator 301 compares a phase of an external clock EXT_CLK with a phase of a feedback clock FB_CLK outputted from the replica model unit 305, which is generated by modeling internal clock delay component of the semiconductor memory device. The phase comparator 301 outputs a comparison signal CMP representing the phase difference between the external clock EXT_CLK and the feedback clock FB_CLK to the delay controller 303.

The delay controller 303 delays the external clock EXT_CLK as much as a first delay amount DD_1 (shown in FIG. 5) in order to match the phases of the external clock EXT_CLK and the feedback clock FB_CLK with each other in response to the comparison signal CMP. The delay controller 303 outputs the delayed clock as an internal clock CLK_DD. The duty cycle ratio corrector 307 corrects a duty cycle ratio of the internal clock CLK_DD and transfers the corrected internal clock RCLK_DLL to the replica model unit 305.

Finally, the feedback clock FB_CLK outputted from the replica model unit 305 is matched with the external clock EXT_CLK in phase because the delay of the delay controller 303 and the delay of the replica model unit 305 are reflected in the feedback clock FB_CLK. Herein, the internal clock CLK_DD with delay reflected by the delay controller 303 becomes to be a locking state in delay.

The duty cycle ratio corrector 307 includes a corrector 309 and a sensor 311. The sensor 311 senses a duty cycle ratio of the internal clocks RCLK_DLL and FCLK_DLL outputted from the corrector 309 and generates sensing signals DCC and DCCB representing a duty cycle ratio of the internal clocks RCLK_DLL and FCLK_DLL. The corrector 309 corrects a duty cycle ratio of the internal clock CLK_DD outputted from the delay controller 303 in response to the sensing signals DCC and DCCB and outputs a positive internal clock RCLK_DLL and a negative internal clock FCLK_DLL, which have an opposite phase and a corrected duty cycle ratio.

FIG. 4 is a diagram illustrating a data input circuit 103 of FIG. 1.

Referring to FIG. 4, the data input circuit 103 includes a data strobe signal input unit 401, a plurality of data input units 403 and 405, and an input controller 407.

The data strobe signal input unit 401 receives a data strobe signal DQS from a memory controller and outputs internal data strobe signals DQS_IN and DQSB_IN to the data input units 403 and 405.

The positive internal data strobe signal DQS_IN has an inverse phase of the negative internal data strobe signal DQSB_IN. The data input unit 403 latches external data DQ from the memory controller and outputs internal data DATA at a rising edge of the internal data strobe signals DQS_IN and DQSB_IN.

The input controller 407 controls the data strobe signal input unit 401 and the data input units 403 and 405 in response to a mode signal MODE according to an operation mode of a semiconductor memory device like the output controller 207 of FIG. 2. For example, the input controller 407 enables first and second input control signals DQ_EN and DQS_EN only for a read operation of a semiconductor memory device, and the data input units 403 and 405 and the data strobe signal input unit 401 are enabled in response to the first and second input control signals DQ_EN and DQS_EN in order to reduce power consumption of the semiconductor memory device.

FIG. 5 is a timing diagram illustrating a data output operation of a data output circuit 101 of FIG. 2.

The delay locked loop generates internal clocks RCLK_DLL and FCLK_DLL by delaying an external clock EXT_CLK as much as a first delay amount DD_1. Although a duty cycle ratio of the external clock EXT_CLK is not 50:50, the delay locked loop generates the internal clocks RCLK_DLL and FCLK_DLL having a duty cycle ratio of 50:50 by the duty corrector 307.

However, the internal clocks RCLK_DLL and FCLK_DLL inputted to the output unit 205, as shown, may be distorted in a duty cycle ratio due to noise or variation of process, voltage, and temperature (PVT variation) while transmitting the internal clocks RCLK_DLL and FCLK_DLL in the second transmission line unit 201. The data output units 209, 211, 213, and 215 outputs external data DQ in response to rising edges of the internal clocks RCLK_DLL and FCLK_DLL with the distorted duty cycle ratio. Therefore, in the conventional data output circuit, a data margin is reduced when the internal data DATA is latched in response to the rising edge of the negative internal clock FCLK_DLL, thereby deteriorating jitter characteristics. Therefore, external data DQ may be distorted in the data output circuit according to the related art.

The external data DQ outputted from the data output units 209, 211, 213, and 215 includes delays of the data output units 209, 211, 213, and 215 and is matched with the external clock EXT_CLK in phase. The data strobe signal DQS generated based on the internal clocks RCLK_DLL and FCLK_DLL also includes delay of the data strobe signal output unit 209 and is matched with the external clock EXT_CLK in phase.

In case of the data input circuit 103, the duty cycle ratio of the internal data strobe signals DQS_IN and DQSB_IN may be distorted by external noise, switching noise of the strobe signal input unit 401, or PVT variation. Such distortion may reduce a data margin when the external data DQ is latched in response to the rising edge of the internal data strobe signal DQSB_IN, and the jitter characteristic deteriorates. Therefore, internal data may be distorted.

That is, in the data input/output circuit according to the related art, the data input unit and the data output unit receive and output data based on the data strobe signal and the internal data strobe signal having distorted duty cycle ratio. Therefore, the data margin is reduced, and the data outputted or inputted to the semiconductor memory device may be distorted.

### SUMMARY OF THE INVENTION

Embodiments of the present invention are directed to providing a data input/output circuit for improving jitter characteristic and securing an enough data margin.

In accordance with an aspect of the present invention, there is provided a data output circuit including an output unit configured to output a data strobe signal and data in response to an internal clock generated in a delay locked loop, a first transmission line unit, having a clock tree structure, configured to transfer the internal clock to the output unit, a second transmission line unit configured to transfer the internal clock from the delay locked loop to the first transmission line unit, and a duty cycle ratio correcting unit, interconnected between the first transmission line unit and the second transmission line unit, configured to correct a duty cycle ratio of the internal clock.

In accordance with another aspect of the present invention, there is provided a data input circuit including a data strobe signal input unit configured to generate an internal data strobe signal in response to a data strobe signal inputted from an outside of a semiconductor memory device, a duty cycle ratio correcting unit configured to correct a duty cycle ratio of the internal data strobe signal and output a corrected data strobe signal, and a plurality of data input units configured to output data inputted from the outside of the semiconductor memory device as internal data in response to the corrected data strobe signal.

In accordance with still another aspect of the present invention, there is provided a data input/output circuit including an output unit configured to output a first data strobe signal and first data in response to an internal clock generated in a delay locked loop, a first transmission line unit, having a clock tree structure, configured to transmit the internal clock to the output unit, a second transmission line unit configured to transmit the internal clock from the delay locked loop to the first transmission line unit, a duty cycle ratio correcting unit, interconnected between the first transmission line unit and the second transmission line unit, configured to correct a duty cycle ratio of the internal clock, a data strobe signal input unit configured to receive a second data strobe signal from an outside of a semiconductor memory device and to generate an internal data strobe signal, and a plurality of data input units configured to output a second data inputted from the outside of the semiconductor memory device in response to the internal data strobe signal.

In accordance with still another aspect of the present invention, there is provided a data output circuit including a transmission line unit configured to transmit a control clock generated in a semiconductor memory device, and an output unit configured to output a data strobe signal and data to an outside of the semiconductor memory device in response to a corrected control clock having a corrected duty cycle ratio obtained by correcting a duty cycle ratio of the transmitted control clock.

### BRIEF DESCRIPTION OF THE DRAWINGS

FIG. 1 is a diagram illustrating a data input/output circuit according to the related art.

FIG. 2 is a diagram illustrating a data output circuit of FIG. 1.

FIG. 3 is a diagram illustrating a delay locked loop recited in FIG. 2.

FIG. 4 is a diagram illustrating a data input circuit of FIG. 1.

FIG. 5 is a timing diagram describing an data output operation of a data output circuit of FIG. 2.

FIG. 6 is a diagram illustrating a data output circuit in accordance to an embodiment of the present invention.

FIG. 7 is a timing diagram describing a data output operation of a data output circuit of FIG. 6.

FIG. 8 is a diagram illustrating a data input circuit in accordance with an embodiment of the present invention.

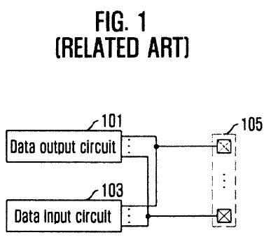

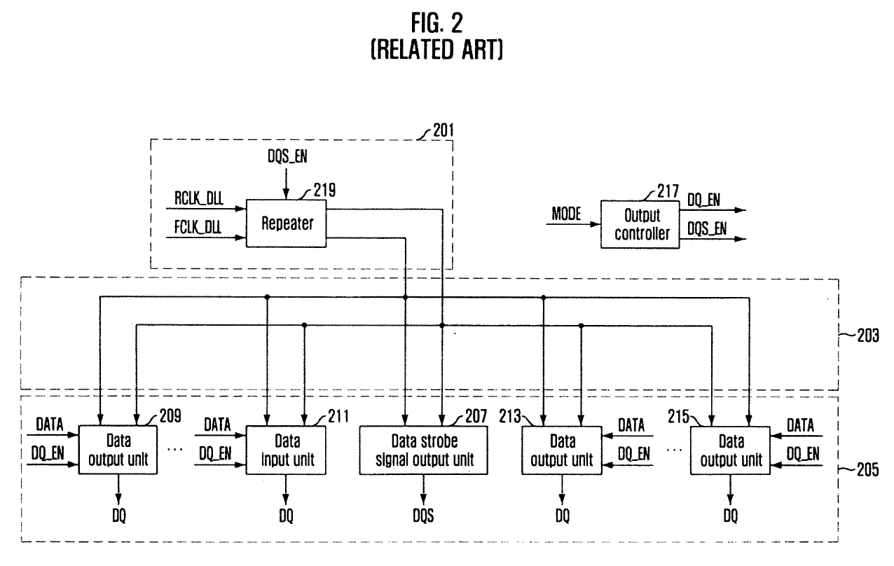

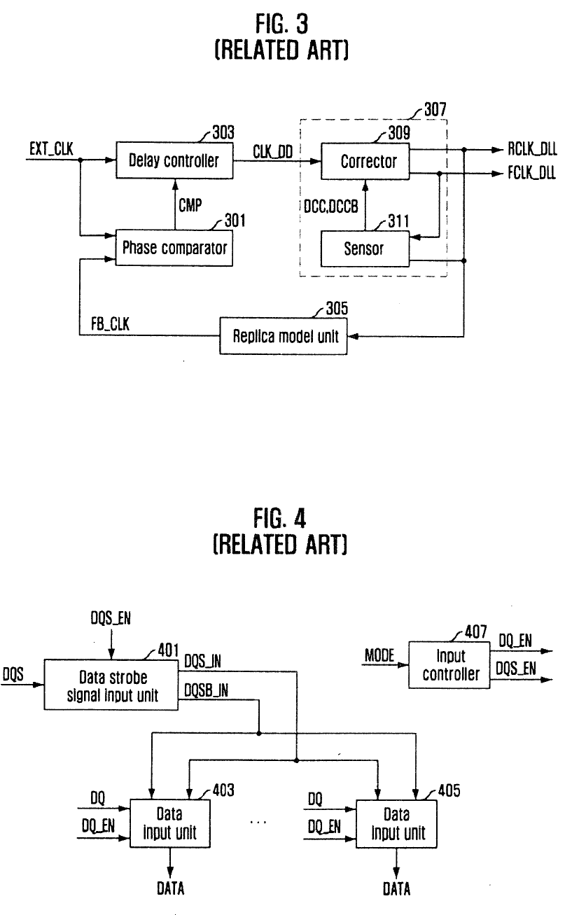

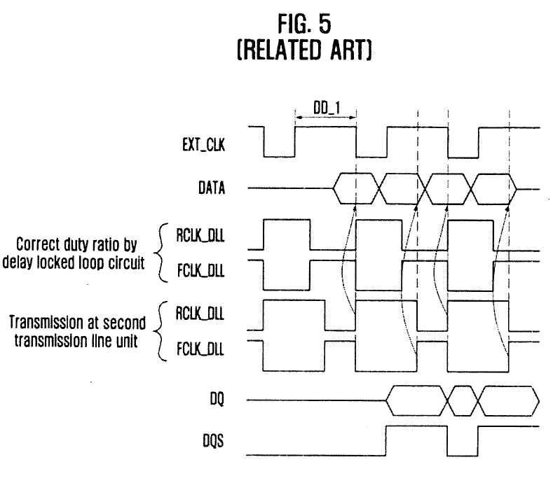

### DESCRIPTION OF SPECIFIC EMBODIMENTS

Other objects and advantages of the present invention can be understood by the following description, and become apparent with reference to the embodiments of the present invention.

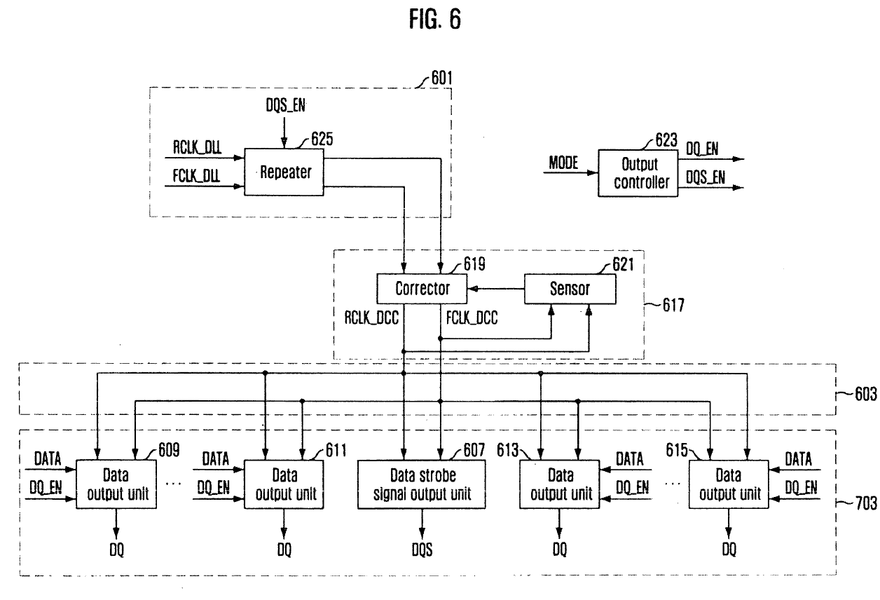

FIG. 6 is a diagram illustrating a data output circuit in accordance with an embodiment of the present invention.

Referring to FIG. 6, the data output circuit according to the present embodiment includes an output unit 605, a first transmission line unit 603, a second transmission line unit 601, an output controller 623, and a duty cycle ratio corrector 617.

Unlike the related art, the data output circuit according to the present embodiment includes a duty cycle ratio corrector 617 disposed between the first transmission line unit 603 and the second transmission line unit 601. Therefore, the data output circuit according to the present embodiment can correct the duty cycle ratio distortion of the internal clocks RCLK_DLL and FCLK_DLL, which may be generated after the internal clocks RCLK_DLL and FCLK_DLL are outputted from the delay locked loop with the duty cycle ratios corrected and before the internal clocks RCLK_DLL and FCLK_DLL are inputted to the second transmission line unit 601. Therefore, it is possible to secure a data margin and improve the jitter characteristic of the data output circuit.

The second transmission line unit 601 transfers the internal clocks RCLK_DLL and FCLK_DLL generated from the delay locked loop to the first transmission line unit 603. Since the length of the transmission line is relatively long, the internal clocks RCLK_DLL and FCLK_DLL may be distorted due to the loading of the transmission line. Therefore, the second transmission line unit 601 may include a repeater 625 for preventing the distortion of the internal clocks RCLK_DLL and FCLK_DLL by driving the internal clocks RCLK_DLL and FCLK_DLL.

The first transmission line unit 603 transfers the internal clocks RCLK_DLL and FCLK_DLL to the output unit 605 that outputs a data strobe signal DQS and data DQ in response to the internal clocks RCLK_DLL and FCLK_DLL. The output unit 605 includes a plurality of data output units 609, 611, 613, and 615, and a data strobe signal output unit 607. The first transmission line unit 603 has a clock tree structure in order to minimize a skew of the internal clocks RCLK_DLL and FCLK_DLL transferred to the data output units 609, 611, 613, and 615, and the data strobe signal output unit 607.

As shown in FIG. 5, the duty cycle ratio of the internal clocks RCLK_DLL and FCLK_DLL may be distorted due to PVT variation. If the data output units 609, 611, 613, and 615 output the external data DQ based on the internal clocks RCLK_DLL and FCLK_DLL having the distorted duty cycle ratio, the external data DQ may be distorted because a data margin is reduced. Therefore, the duty cycle ratio corrector 617 is disposed in front of the first transmission line unit 603 and corrects the duty cycle ratio of the internal clocks RCLK_DLL and FCLK_DLL from the second transmission line 601 to a duty cycle ratio of 50:50.

The duty corrector 617 includes a sensor 621 and a corrector 619. The sensor 621 senses the duty cycle ratios of the corrected internal clocks RCLK_DCC and FCLK_DCC outputted from the corrector 619, and generates sensing signals DCC and DCCB representing the duty cycle ratios of the corrected internal clocks RCLK_DCC and FCLK_DCC. The corrector 619 corrects the duty cycle ratios of the internal clocks RCLK_DLL and FCLK_DLL in response to the sensing signals DCC and DCCB.

For example, the sensor 621 may generate sensing signals DCC and DCCB that can be charged or discharged according to widths of a high level period and a low level period of the corrected internal clocks RCLK_DCC and FCL_DCC. For example, if the width of the high level period of the corrected internal clocks RCLK_DCC and FCLK_DCC is wider than that of the low level period, the sensing signal DCC may transit to a high level, and the sensing signal DCCB may transit to a low level.

The corrector 619 decides whether to increase the width of the high level period of the internal clocks RCLK_DLL and FCLK_DLL or to increase the width of the low level period based on the sensing signals DCC and DCCB that transit to the opposite level. In above case, the corrector 619 corrects the duty cycle ratios of the internal clocks RCLK_DLL and FCLK_DLL to a duty cycle ratio of 50:50 by narrowing down the width of the high level period of the internal clocks RCLK_DLL and FCLK_DLL and by lengthening the width of the low level period of them.

Since distortion of duty cycle ratios of the positive and negative internal clocks RCLK_DLL and FCLK_DLL may be different, the duty corrector 617 independently corrects a duty cycle ratio of each of the positive and negative internal clocks RCLK_DLL and FCLK_DLL.

The data strobe signal output unit 607 outputs a data strobe signal DQS to a memory controller by driving the corrected internal clocks RCLK_DCC and FCLK_DCC. Each of the data output units 609, 611, 613, and 615 is connected to a DQ pad, latches internal data DATA outputted from a memory cell of a semiconductor memory device at rising edges of the corrected internal clocks RCLK_DCC and FCLK_DCC, and outputs the latched internal data to the memory controller.

The output controller 623 controls the output unit 605 in response to a mode signal MODE according to an operation mode of the semiconductor memory device. For example, in case of a write operation of a semiconductor memory device, the semiconductor memory device receives data and a data strobe signal from an external device and does not output the external data DQ and the data strobe signal DQS to the external device. Therefore, the operation of the semiconductor memory device is not influenced although the output unit 605 is disabled. Even in case of a read operation of the semiconductor memory device, the output unit 605 does not output the external data DQ and the data strobe signal DQS during a clock cycle corresponding to a CAS latency CL. Therefore, the operation of the semiconductor memory device is not influenced although the output unit 605 is disabled for a clock cycle corresponding to the CAS latency.

Therefore, the output controller 623 enables the first output control signal DQ_EN only for the corresponding read operation of the semiconductor memory device, and the data output units 609, 611, 613, and 615 are enabled and output the external data DQ in response to the first output control signal DQ_EN in order to reduce power consumption. The output controller 623 also enables the second output control signal DQS_EN and the repeater 625 outputs the internal clocks RCLK_DLL and FCLK_DLL in response to the second output control signal DQS_EN. According to design, the data strobe signal output unit 609 may output a data strobe signal DQS in response to the second control signal DQS_EN.

As described above, the data output circuit according to the present embodiment secures a data margin and improves the jitter characteristic by correcting the duty cycle ratio distortion of the internal clocks RCLK_DLL and FCLK_DLL before the output unit 605.

Although the data output circuit according to the present embodiment outputs data in response to the internal clocks RCLK_DLL and FCLK_DLL outputted from the delay locked loop in FIG. 6, the present invention is not limited thereto. That is, a data output circuit according to another embodiment of the present invention can output data in response to a predetermined control clock. Here, the data output circuit according to the another embodiment can also secure a data margin and improve the jitter characteristic because the data and the data strobe signal are outputted in response to the control clock with a duty cycle ratio corrected.

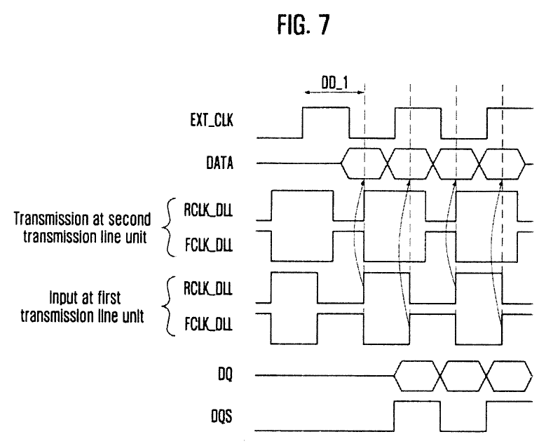

FIG. 7 is a timing diagram illustrating a data output operation of a data output circuit of FIG. 6.

The delay locked loop generates internal clocks RCLK_DLL and FCLK_DLL by delaying an external clock EXT_CLK having a duty cycle ratio of 50:50 as much as a first delay amount DD_1. The duty cycle ratios of the internal clocks RCLK_DLL and FCLK_DLL are distorted by noise entered while the internal clocks RCLK_DLL and FCLK_DLL are transmitted through the second transmission line unit 601.

The duty cycle ratio corrector 617 corrects the internal clocks RCLK_DLL and FCLK_DLL having the distorted duty cycle ratio and outputs the corrected internal clocks RCLK_DCC and FCLK_DCC having a duty cycle ratio of 50:50.

Unlike FIG. 5, the data output units 609, 611, 613, and 615 output not-distorted external data DQ because internal data DATA is latched by securing a data margin at rising edges of the corrected internal clocks RCLK_DCC and FCLK_DCC.

Meanwhile, the phases of the external data DQ and the data strobe signal DQS are matched with the phase of the external clock EXT_CLK.

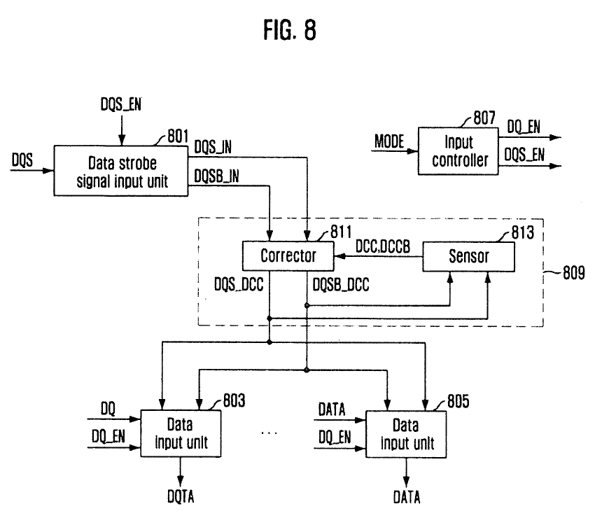

FIG. 8 is a diagram illustrating a data input circuit in accordance with an embodiment of the present invention.

Referring to FIG. 8, the data input circuit according to the present embodiment includes a data strobe signal input unit 801, a plurality of data input units 803 and 805, an input controller 807, and a duty cycle ratio corrector 809.

Unlike the related art, the data input circuit according to the present embodiment includes the duty cycle ratio corrector 809 for correcting a duty cycle ratio of internal data strobe signals DQS_IN and DQSB_IN outputted from the data strobe signal input unit 801. Therefore, a data margin is secured and the jitter characteristic of the data input circuit is improved since the data input circuit according to the present embodiment can correct the duty cycle ratio distortion of the internal data strobe signals DQS_IN and DQSB_IN

The data strobe signal input unit 801 receives a data strobe signal DQS from a memory controller and outputs the internal data strobe signals DQS_IN and DQSB_IN.

The duty cycle ratio corrector 809 corrects the duty cycle ratios of the internal data strobe signals DQS_IN and DQSB_IN and outputs corrected data strobe signals DQS_DCC and DQSB_DCC to the data input units 803 and 805. Since the duty cycle ratio correct 809 has a structure similar to that of the duty cycle ratio correction 617 of FIG. 6, detail description thereof is omitted.

The positive corrected data strobe signal DQS_DCC has a reverse phase of the negative corrected data strobe signal DQSB_DCC. The data input units 803 and 805 latch external data DQ at rising edges of the corrected data strobe signals DQS_DCC and DQSB_DCC and output internal data DATA.

The input controller 807 controls the data strobe signal input unit 801 and the data input units 803 and 805 in response to a mode signal MODE according to an operation mode of the semiconductor memory device like the output controller 623 of FIG. 6. For example, in case of a read operation of the semiconductor memory device, the data input units 803 and 805 and the data strobe signal input unit 801 do not receive the external data DQ and the data strobe signal DQS from the memory controller. Therefore, the operation of the semiconductor memory device is not influenced although the data input units 803 and 805 and the data strobe signal input unit 801 are disabled. Therefore, the input controller 807 enables the first and second input signals DQ_EN and DQS_EN only for the write operation of the semiconductor memory device, and the data input units 803 and 805 and the data strobe signal input unit 801 are enabled in response to the first and second input control signals DQ_EN and DQS_EN, respectively in order to reduce power consumption.

In other word, the data input circuit according to the present embodiment can secure a data margin and improve jitter characteristic by correcting the duty cycle ratio distortion of the internal data strobe signals DQS_IN and DQSB_IN.

In accordance with the present invention, the data input/output circuit corrects the duty cycle ratio of control signals, which is used at the data input/output, by including the duty cycle ratio corrector. Therefore, jitter characteristic of the data input/output circuit is improved and the enough data margin is secured.

While the present invention has been described with respect to the specific embodiments, it will be apparent to those skilled in the art that various changes and modifications may be made without departing from the spirit and scope of the invention as defined in the following claims.

What is claimed is:

1. A data output circuit, comprising:
an output unit configured to output a data strobe signal and data in response to an internal clock generated in a delay locked loop;
a first transmission line unit, having a clock tree structure, configured to transfer the internal clock to the output unit;
a second transmission line unit configured to transfer the internal clock from the delay locked loop to the first transmission line unit; and
a duty cycle ratio correcting unit, interconnected between the first transmission line unit and the second transmission line unit, configured to correct a duty cycle ratio of the internal clock.

2. The data output circuit of claim 1, wherein the duty cycle ratio correcting unit includes:
a sensor configured to sense the duty cycle ratio of the internal clock and generate a sensing signal; and
a corrector configured to correct the duty cycle ratio of the internal clock in response to the sensing signal.

3. The data output circuit of claim 1, further comprising an output controller configured to control turning on/off of the output unit according to an operation mode of a semiconductor memory device.

4. The data output circuit of claim 1, wherein the output unit includes:
a plurality of data output units configured to output the data in response to the internal clock; and
a data strobe signal output unit configured to output the data strobe signal by driving the internal clock.

5. The data output circuit of claim 1, wherein the second transmission line unit includes a repeater to drive the internal clock.

6. A data input circuit, comprising:
a data strobe signal input unit configured to generate an internal data strobe signal in response to a data strobe signal inputted from an outside of a semiconductor memory device;
a duty cycle ratio correcting unit configured to correct a duty cycle ratio of the internal data strobe signal and output a corrected data strobe signal; and
a plurality of data input units configured to output data inputted from the outside of the semiconductor memory device as internal data in response to the corrected data strobe signal.

7. The data input circuit of claim 6, wherein the duty cycle ratio correcting unit includes:
a sensor configured to generate a sensing signal by sensing the duty cycle ratio of the internal data strobe signal; and
a corrector configured to correct the duty cycle ratio of the internal data strobe signal in response to the sensing signal.

8. The data input circuit of claim 6, further comprising an input controller configured to control turning on/off of the data strobe signal input unit according to an operation mode of the semiconductor memory device.

9. The data input circuit of claim 8, wherein the input controller controls turning on/off of the plurality of data input units according to the operation mode.

10. A data input/output circuit, comprising:
an output unit configured to output a first data strobe signal and first data in response to an internal clock generated in a delay locked loop;
a first transmission line unit, having a clock tree structure, configured to transmit the internal clock to the output unit;
a second transmission line unit configured to transmit the internal clock from the delay locked loop to the first transmission line unit;
a duty cycle ratio correcting unit, interconnected between the first transmission line unit and the second transmission line unit, configured to correct a duty cycle ratio of the internal clock;
a data strobe signal input unit configured to receive a second data strobe signal from an outside of a semiconductor memory device and to generate an internal data strobe signal; and
a plurality of data input units for outputting a second data inputted from the outside of the semiconductor memory device in response to the internal data strobe signal.

11. The data input/output circuit of claim 10, wherein the duty cycle ratio correcting unit includes:
a sensor configured to sense the duty cycle ratio of the internal clock and to generate a sensing signal; and
a corrector configured to correct the duty cycle ratio of the internal clock in response to the sensing signal.

12. The data input/output circuit of claim 10, wherein the output unit includes:
a plurality of data output units configured to output the first data in response to the internal clock; and
a data strobe signal output unit configured to output the first data strobe signal by driving the internal clock.

13. The data input/output circuit of claim 10, further comprising a duty cycle ratio correcting unit configured to correct a duty cycle ratio of the internal data strobe signal.

14. A data output circuit, comprising:
a transmission line unit configured to transmit a control clock generated in a semiconductor memory device; and
an output unit configured to output a data strobe signal and data to an outside of the semiconductor memory device in response to a corrected control clock having a corrected duty cycle ratio obtained by correcting a duty cycle ratio of the transmitted control clock.

15. The data output circuit of claim 14, wherein the control clock is outputted from a delay locked loop.

16. The data output circuit of claim 14, wherein the output unit includes:
a sensor configured to generate a sensing signal by sensing the duty cycle ratio of the transmitted control clock;
a corrector configured to correct the duty cycle ratio of the transmitted control clock in response to the sensing signal;
a plurality of data output units configured to output the data in response to the corrected control clock; and
a data strobe signal output unit configured to output the data strobe signal by driving the corrected control clock.

17. The data output circuit of claim 14, further comprising an output controller configured to control turning on/off of the output unit according to an operation mode of the semiconductor memory device.
